(19) United States
(12) Patent Application Publication
(10) Pub. No.: US 2014/0155591 A1
(43) Pub. Date: Jun. 5, 2014

(54) ARYLAMINE COMPOUND AND ELECTROLUMINESCENCE DEVICE INCLUDING THE SAME

(71) Applicant: Samsung Display Co., Ltd., Yongin-City (KR)

(72) Inventor: Ichinori TAKADA, Yongin-City (KR)

(73) Assignee: Samsung Display Co., Ltd., Yongin-City (KR)

(21) Appl. No.: 14/087,111

(22) Filed: Nov. 22, 2013

(30) Foreign Application Priority Data
Nov. 30, 2012 (JP) 2012-263842

(51) Int. Cl. H01L 51/00

(52) U.S. Cl. CPC H01L 51/0071
USPC 544/37

(57) ABSTRACT

An arylamine compound and an organic electroluminescence device, the compound being represented by following Formula 1:

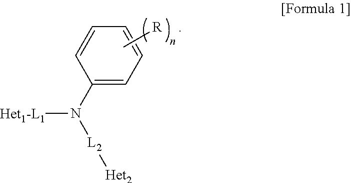

### CROSS-REFERENCE TO RELATED APPLICATION

Japanese Patent Application No. 2012-263842, filed on Nov. 30, 2012, in the Japanese Patent Office, and entitled: “ARYLAMINE COMPOUND AND ELECTROLUMINESCENCE DEVICE COMPRISING THE SAME,” is incorporated by reference herein in its entirety.

### BACKGROUND

1. Field

Embodiments to an arylamine compound and an electroluminescence device including the same.

2. Description of the Related Art

In recent years, organic electroluminescence (EL) displays are one type of image displays that have been actively developed. Unlike a liquid crystal display (or the like), the organic EL display is so-called a self-luminescent display that recombines holes and electrons injected from an anode and a cathode in a light-emitting layer to thus emit light from a light-emitting material including an organic compound, thereby displaying an image.

An example of a light-emitting device (hereinafter referred to as an organic EL device) may include an organic EL device that includes a positive electrode, a hole transport layer disposed on the positive electrode, a light-emitting layer disposed on the hole transport layer, an electron transport layer disposed on the light-emitting layer, and a negative electrode disposed on the electron transport layer. Holes injected from the positive electrode may be injected into the light-emitting layer via the hole transport layer. Electrons may be injected from the negative electrode, and then injected into the light-emitting layer via the electron transport layer. The holes and the electrons injected into the light-emitting layer may be recombined to generate excitons within the light-emitting layer. The organic EL device may emit light generated by radiation and deactivation of the excitons.

### SUMMARY

Embodiments are directed to an arylamine compound and an electroluminescence device including the same.

The embodiments may be realized by providing an arylamine compound represented by following Formula 1:

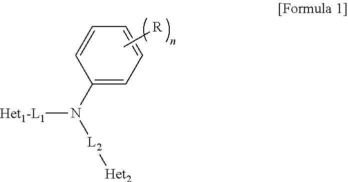

wherein a structure represented by Het₁-L₁ and a structure represented by Het₂-L₂ are different, L₁ and L₂ are each independently a single bond or a bivalent group derived from an alkane, an arene, or a heteroarene having 1 to 20 carbon atoms, Het₁ and Het₂ are each independently a dibenzopiperidine derivative substituent having less than or equal to 20 carbon atoms, and R is a hydrogen atom, a deuterium atom, a fluorine atom, a chlorine atom, a cyano group, a trifluoromethyl group, a nitro group, a substitutable alkyl group having a straight or branched chain of 1 to 6 carbon atoms, a substitutable cycloalkyl group of 5 to 20 carbon atoms, a substitutable alkenyl group having a straight or branched chain of 2 to 6 carbon atoms, a substitutable alkyloxy group having a straight or branched chain of 1 to 6 carbon atoms, a substitutable cycloalkyloxy group, a substituted or unsubstituted aromatic hydrocarbon group, a substituted or unsubstituted aromatic heterocyclic group, a substituted or unsubstituted condensed polycyclic aromatic group, or a substituted or unsubstituted aryloxy group having 5 to 20 carbon atoms, in which monovalent, divalent, or adjacent two substituents may have a cyclic structure, and n is an integer of 0 to 7.

The arylamine compound may be represented by following Formula 2:

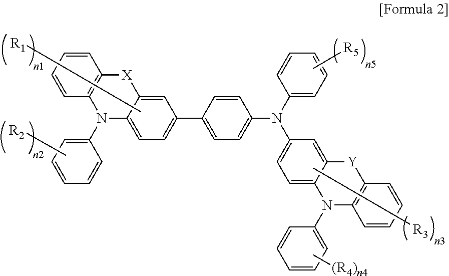

wherein X is a methylene group, a nitrogen atom, an oxygen atom, or a sulfur atom, Y is a methylene group, an oxygen atom, or a sulfur atom, and R₁ to R₅ are each independently a hydrogen atom, a deuterium atom, a fluorine atom, a chlorine atom, a cyano group, a trifluoromethyl group, a nitro group, a substitutable alkyl group having a straight or branched chain of 1 to 6 carbon atoms, a substitutable cycloalkyl group of 5 to 20 carbon atoms, a substitutable alkenyl group having a straight or branched chain of 2 to 6 carbon atoms, a substitutable alkyloxy group having a straight or branched chain of 1 to 6 carbon atoms, a substitutable cycloalkyloxy group, a substituted or unsubstituted aromatic hydrocarbon group, a substituted or unsubstituted aromatic heterocyclic group, a substituted or unsubstituted condensed polycyclic aromatic group, or a substituted or unsubstituted aryloxy group having 5 to 20 carbon atoms, in which monovalent, divalent or adjacent two substituents may have a cyclic structure, and n₁ to n₅ are each independently an integer of 0 to 7.

The embodiments may be realized by providing an organic electroluminescence device including a hole transport layer formed by using a compound represented by following Formula 1:

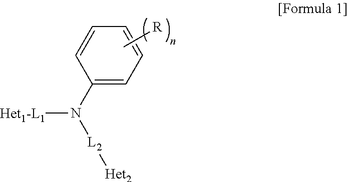

wherein a structure represented by Het₁-L₁ and a structure represented by Het₂-L₂ are different, L₁ and L₂ are each independently a single bond or a bivalent group derived from an alkane, an arene, or a heteroarene having 1 to 20 carbon atoms, Het₁ and Het₂ are each independently a dibenzopiperidine derivative substituent having less than or equal to 20 carbon atoms, and R is a hydrogen atom, a deuterium atom, a fluorine atom, a chlorine atom, a cyano group, a trifluoromethyl group, a nitro group, a substitutable alkyl group having a straight or branched chain of 1 to 6 carbon atoms, a substitutable cycloalkyl group of 5 to 20 carbon atoms, a substitutable alkenyl group having a straight or branched chain of 2 to 6 carbon atoms, a substitutable alkyloxy group having a straight or branched chain of 1 to 6 carbon atoms, a substitutable cycloalkyloxy group, a substituted or unsubstituted aromatic hydrocarbon group, a substituted or unsubstituted aromatic heterocyclic group, a substituted or unsubstituted condensed polycyclic aromatic group, or a substituted or unsubstituted aryloxy group having 5 to 20 carbon atoms, in which monovalent, divalent, or adjacent two substituents may have a cyclic structure, and n is an integer of 0 to 7.

The arylamine compound is represented by following Formula 2:

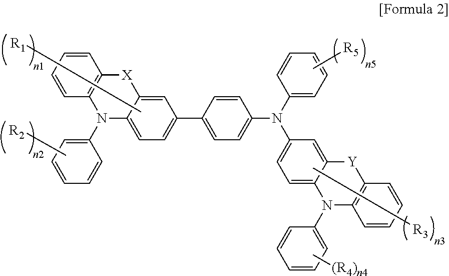

wherein X is a methylene group, a nitrogen atom, an oxygen atom, or a sulfur atom, Y is a methylene group, an oxygen atom, or a sulfur atom, and R₁ to R₅ are each independently a hydrogen atom, a deuterium atom, a fluorine atom, a chlorine atom, a cyano group, a trifluoromethyl group, a nitro group, a substitutable alkyl group having a straight or branched chain of 1 to 6 carbon atoms, a substitutable cycloalkyl group of 5 to 20 carbon atoms, a substitutable alkenyl group having a straight or branched chain of 2 to 6 carbon atoms, a substitutable alkyloxy group having a straight or branched chain of 1 to 6 carbon atoms, a substitutable cycloalkyloxy group, a substituted or unsubstituted aromatic hydrocarbon group, a substituted or unsubstituted aromatic heterocyclic group, a substituted or unsubstituted condensed polycyclic aromatic group, or a substituted or unsubstituted aryloxy group having 5 to 20 carbon atoms, in which monovalent, divalent or adjacent two substituents are separate or have a cyclic structure, and n₁ to n₅ are each independently an integer of 0 to 7.

### BRIEF DESCRIPTION OF THE DRAWING

Features will be apparent to those of skill in the art by describing in detail exemplary embodiments with reference to the attached drawing in which:

FIG. 1 illustrates a schematic diagram of an organic EL device according to an embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figure, the dimensions of layers and regions may be exaggerated for clarity of illustration. Like reference numerals refer to like elements throughout.

The embodiments provide arylamine compound including one pair of structures composed of a connecting part or linking group and a dibenzopiperidine derivative. The compound according to an embodiment may help improve charge transport performance of a hole transport layer and may help improve electron durability. Accordingly, an organic EL device having high efficiency and long life may be prepared.

In an implementation, in the benzopiperidine derivative described herein, the position 4 of piperidine may be substituted or replaced with oxygen or sulfur.

The arylamine compound according to an embodiment may be represented by the following Formula 1. For example, part (A) including Het₁-L₁ and part (B) including Het₂-L₂ may have different structures. In addition, the arylamine compound according to an embodiment may include part (C), in which an aryl group is bonded to the nitrogen of an amine.

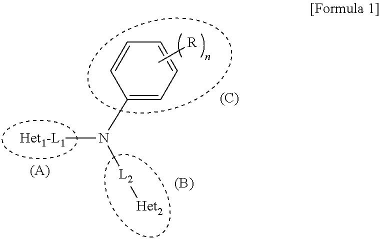

In the arylamine compound of Formula 1, L₁ and L₂ are connecting parts or linking groups, and may each independently include a single bond or a bivalent group derived from an alkane, an arene, or a heteroarene having 1 to 20 carbon atoms. In the arylamine compound according to an embodiment, part (A) and part (B) may be different. For example, L₁ and L₂ may have the same structure an Het₁ and Het₂ may be different. Het₁ and Het₂ may be substituents of dibenzopiperidine derivatives having less than or equal to 20 carbon atoms. In an implementation, Het₁ and Het₂ may have the same structure and L₁ and L₂ may be different. In the arylamine compound according to an embodiment, Het₁ and Het₂ may have different structures as described below.

R may be a hydrogen atom, a deuterium atom, a fluorine atom, a chlorine atom, a cyano group, a trifluoromethyl group, a nitro group, a substitutable alkyl group having a straight or branched chain of 1 to 6 carbon atoms, a substitutable cycloalkyl group of 5 to 20 carbon atoms, a substitutable alkenyl group having a straight or branched chain of 2 to 6 carbon atoms, a substitutable alkyloxy group having a straight or branched chain of 1 to 6 carbon atoms, a substitutable cycloalkyloxy group, a substituted or unsubstituted aromatic hydrocarbon group, a substituted or unsubstituted aromatic heterocyclic group, a substituted or unsubstituted condensed polycyclic aromatic group, or a substituted or unsubstituted aryloxy group having 5 to 20 carbon atoms. In an implementation, monovalent, divalent, or adjacent two substituents may be separate or may have a cyclic structure. n may be an integer of 0 to 7, e.g., 0 to 5.

The arylamine compound according to an embodiment may be represented by the following Formula 2.

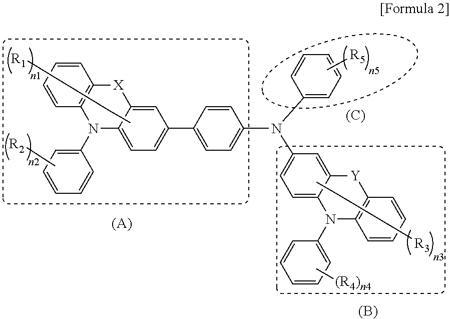

In Formula 2, X may be a methylene group, a nitrogen atom, an oxygen atom, or a sulfur atom. Part (A) may be selected from a dihydroacridinyl group, a dihydrophenazinyl group, a phenoxazinyl group, and a phenothiazinyl group. In an implementation, X may be the methylene group, the nitrogen atom, the oxygen atom, or the sulfur atom. When part (A) has the above-described structure, the arylamine compound according to an embodiment may exhibit improved charge transport performance in a hole transport layer, and an organic EL device including the same may be driven at a low voltage. In the arylamine compound according to an embodiment, Y may be a methylene group, an oxygen atom, or a sulfur atom. In an implementation, part (B) may be selected from a dihydroacridinyl group, a phenoxazinyl group, and a phenothiazinyl group. When part (B) has the above-described structure, the arylamine compound according to an embodiment may exhibit improved electron durability in a hole transport layer, and an organic EL device having increased life may be obtained.

In the arylamine compound according to an embodiment, R₁ to R₅ may each independently be a hydrogen atom, a deuterium atom, a fluorine atom, a chlorine atom, a cyano group, a trifluoromethyl group, a nitro group, a substitutable alkyl group having a straight or branched chain of 1 to 6 carbon atoms, a substitutable cycloalkyl group of 5 to 20 carbon atoms, a substitutable alkenyl group having a straight or branched chain of 2 to 6 carbon atoms, a substitutable alkyloxy group having a straight or branched chain of 1 to 6 carbon atoms, a substitutable cycloalkyloxy group, a substituted or unsubstituted aromatic hydrocarbon group, a substituted or unsubstituted aromatic heterocyclic group, a substituted or unsubstituted condensed polycyclic aromatic group, or a substituted or unsubstituted aryloxy group having 5 to 20 carbon atoms. In an implementation, monovalent, divalent, or adjacent two substituents may be separate or may have a cyclic structure. n₁ to n₅ may each independently be an integer of 0 to 7. For example, n₁ and n₃ may each independently be an integer of 0 to 7, and n₂, n₄, and n₅ may each independently be an integer of 0 to 5. In an implementation, in Formula 2, R₁ to R₅ may be introduced in a substitutable optional site of the arylamine compound by the number of n₁ to n₅, respectively.

The arylamine compound according to an embodiment may be represented by one of the following Compounds 7 to 12.

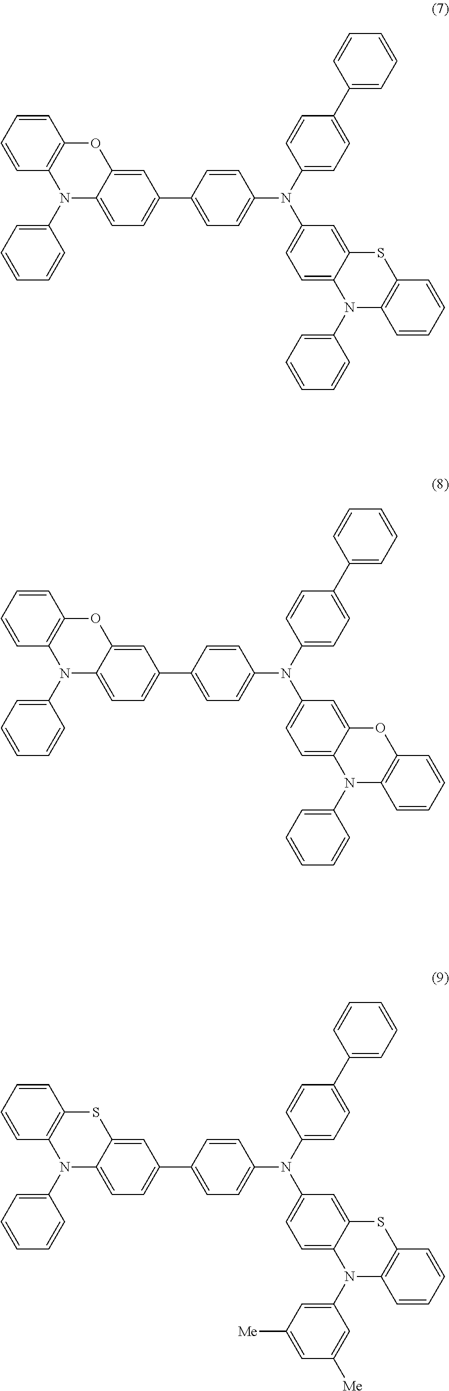 [SMILES: c1ccc(-c2ccc(N(c3ccc(-c4ccc5c(c4)Oc4ccccc4N5c4ccccc4)cc3)c3ccc4c(c3)Sc3ccccc3N4c3ccccc3)cc2)cc1 ; c1ccc(-c2ccc(N(c3ccc(-c4ccc5c(c4)Oc4ccccc4N5c4ccccc4)cc3)c3ccc4c(c3)Oc3ccccc3N4c3ccccc3)cc2)cc1 ; Cc1cc(C)cc(N2c3ccccc3Sc3cc(N(c4ccc(-c5ccccc5)cc4)c4ccc(-c5ccc6c(c5)Sc5ccccc5N6c5ccccc5)cc4)ccc32)c1]

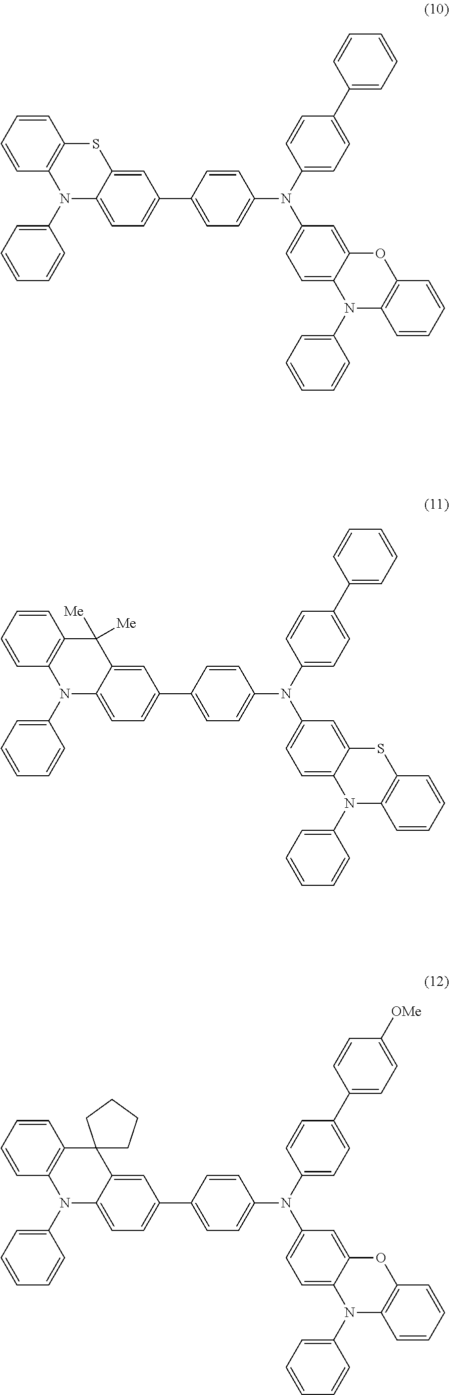 [SMILES: c1ccc(-c2ccc(N(c3ccc(-c4ccc5c(c4)Sc4ccccc4N5c4ccccc4)cc3)c3ccc4c(c3)Oc3ccccc3N4c3ccccc3)cc2)cc1 ; CC1(C)c2ccccc2N(c2ccccc2)c2ccc(-c3ccc(N(c4ccc(-c5ccccc5)cc4)c4ccc5c(c4)Sc4ccccc4N5c4ccccc4)cc3)cc21 ; COc1ccc(-c2ccc(N(c3ccc(-c4ccc5c(c4)C4(CCCC4)c4ccccc4N5c4ccccc4)cc3)c3ccc4c(c3)Oc3ccccc3N4c3ccccc3)cc2)cc1]

In an implementation, the arylamine compound according to an embodiment may be represented by one of the following Compounds 13 to 18.

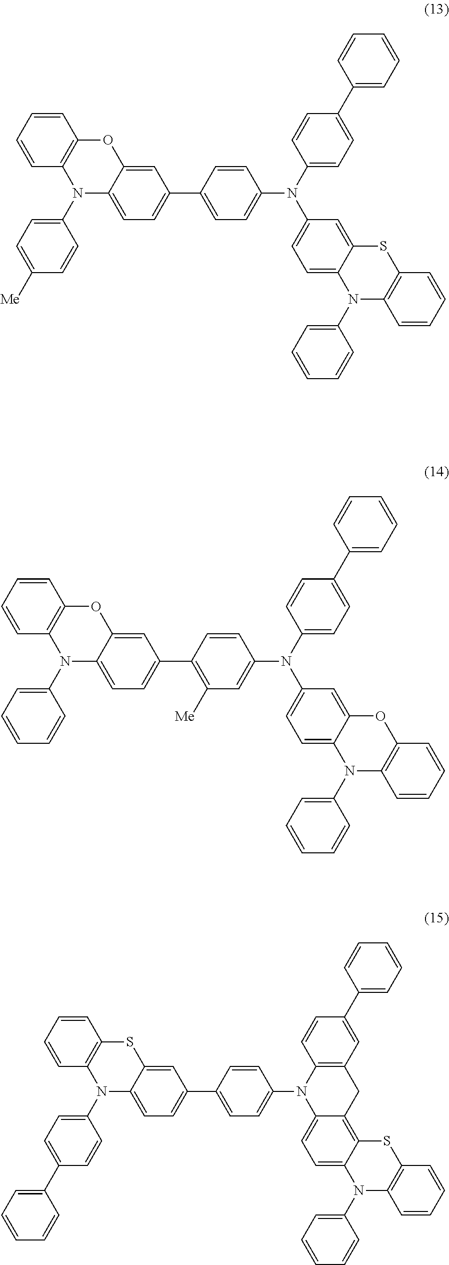 [SMILES: Cc1ccc(N2c3ccccc3Oc3cc(-c4ccc(N(c5ccc(-c6ccccc6)cc5)c5ccc6c(c5)Sc5ccccc5N6c5ccccc5)cc4)ccc32)cc1 ; Cc1cc(N(c2ccc(-c3ccccc3)cc2)c2ccc3c(c2)Oc2ccccc2N3c2ccccc2)ccc1-c1ccc2c(c1)Oc1ccccc1N2c1ccccc1 ; c1ccc(-c2ccc(N3c4ccccc4Sc4cc(-c5ccc(N6c7ccc(-c8ccccc8)cc7Cc7c6ccc6c7Sc7ccccc7N6c6ccccc6)cc5)ccc43)cc2)cc1]

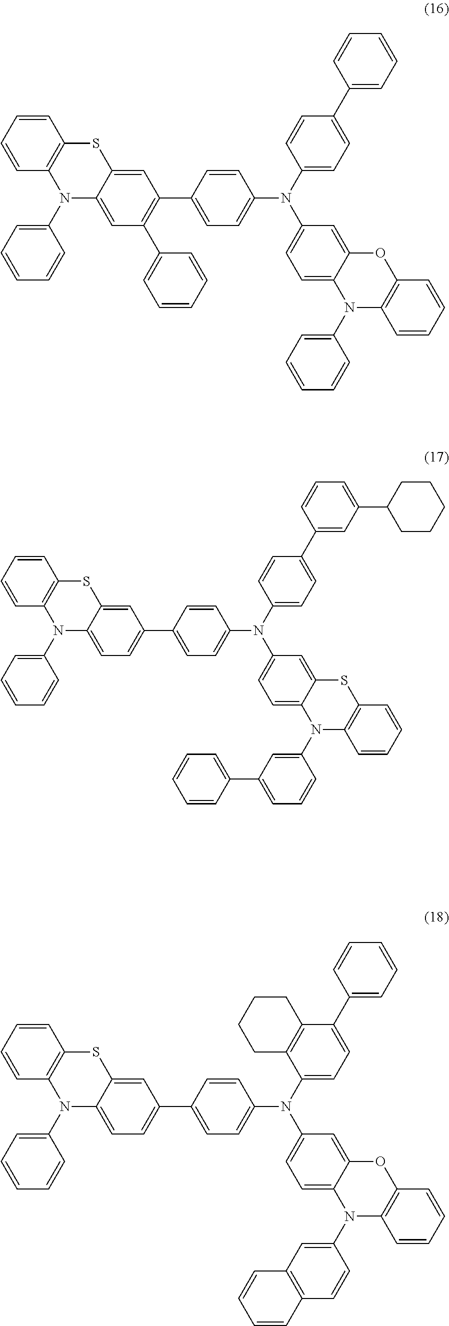 [SMILES: c1ccc(-c2ccc(N(c3ccc(-c4cc5c(cc4-c4ccccc4)N(c4ccccc4)c4ccccc4S5)cc3)c3ccc4c(c3)Oc3ccccc3N4c3ccccc3)cc2)cc1 ; c1ccc(-c2cccc(N3c4ccccc4Sc4cc(N(c5ccc(-c6cccc(C7CCCCC7)c6)cc5)c5ccc(-c6ccc7c(c6)Sc6ccccc6N7c6ccccc6)cc5)ccc43)c2)cc1 ; c1ccc(-c2ccc(N(c3ccc(-c4ccc5c(c4)Sc4ccccc4N5c4ccccc4)cc3)c3ccc4c(c3)Oc3ccccc3N4c3ccc4ccccc4c3)c3c2CCCC3)cc1]

In an implementation, the arylamine compound according to an embodiment may be represented by one of the following Compounds 19 to 22.

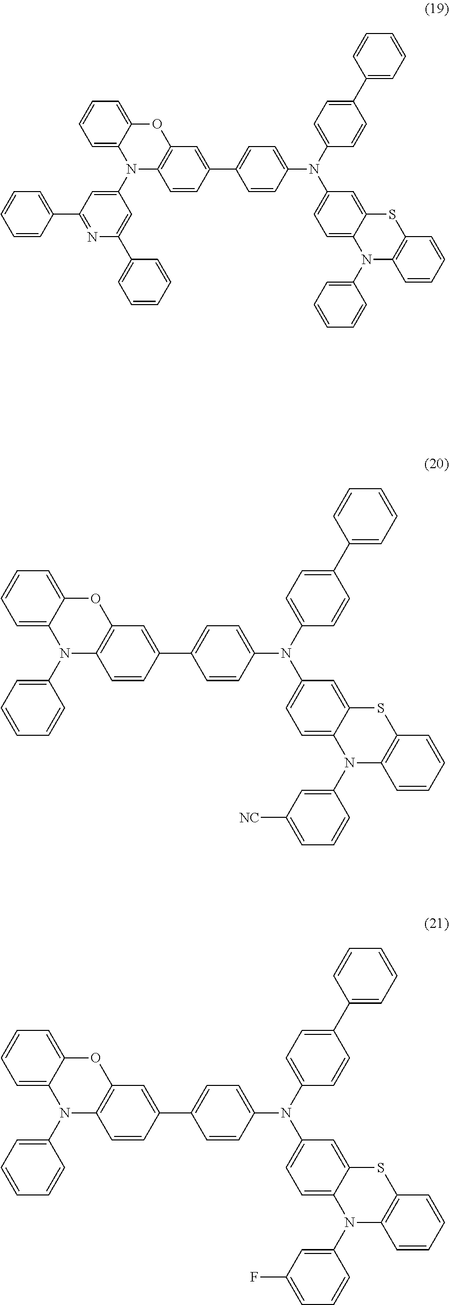 [SMILES: c1ccc(-c2ccc(N(c3ccc(-c4ccc5c(c4)Oc4ccccc4N5c4cc(-c5ccccc5)nc(-c5ccccc5)c4)cc3)c3ccc4c(c3)Sc3ccccc3N4c3ccccc3)cc2)cc1 ; N#Cc1cccc(N2c3ccccc3Sc3cc(N(c4ccc(-c5ccccc5)cc4)c4ccc(-c5ccc6c(c5)Oc5ccccc5N6c5ccccc5)cc4)ccc32)c1 ; Fc1cccc(N2c3ccccc3Sc3cc(N(c4ccc(-c5ccccc5)cc4)c4ccc(-c5ccc6c(c5)Oc5ccccc5N6c5ccccc5)cc4)ccc32)c1]

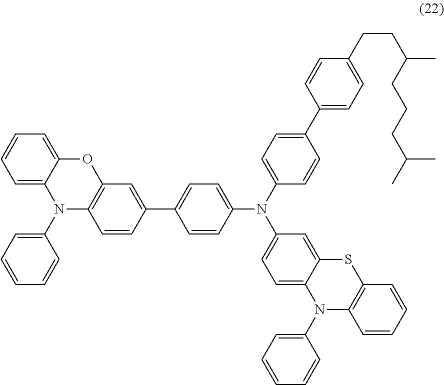 [SMILES: CC(C)CCCC(C)CCc1ccc(-c2ccc(N(c3ccc(-c4ccc5c(c4)Oc4ccccc4N5c4ccccc4)cc3)c3ccc4c(c3)Sc3ccccc3N4c3ccccc3)cc2)cc1]

The arylamine compound according to an embodiment may have the above-described chemical structures and may form a hole transport layer having high efficiency and long life in an organic EL device. The arylamine compound according to an embodiment may include a pair of different structures containing a connecting part and a dibenzopiperidine derivative substituent and may help improve charge transport performance. In addition, the arylamine compound may include a dibenzofuranyl group or a dibenzothiophenyl group and may help improve the durability of electrons. The arylamine compound according an embodiment may include substituents having different structures at three bonding sites of a tertiary amine, and may have an asymmetric structure, thereby restraining crystallization while forming a hole transport layer. In addition, in the dibenzopiperidine derivative substituent, a piperidine part may become a crooked structure. Thus, coplanarity may be decreased, and crystallization during forming the hole transport layer may be restrained and/or suppressed.

Organic EL Device

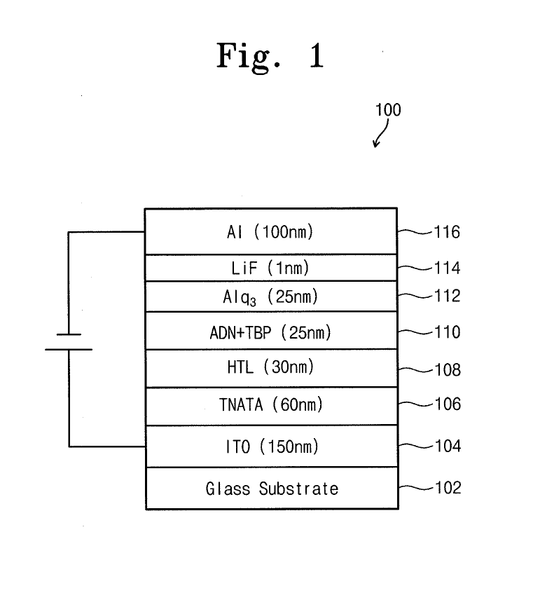

An organic EL device using the arylamine compound according to an embodiment as a hole transport material for the organic EL device will be explained. FIG. 1 illustrates a schematic diagram of an organic EL device 100 according to an embodiment. The organic EL device 100 may include, e.g., a substrate 102, a positive electrode 104, a hole injection layer 106, a hole transport layer 108, an emission layer 110, an electron transport layer 112, an electron injection layer 114, and a negative electrode 116.

The substrate 102 may be, e.g., a transparent glass substrate, a flexible substrate of a semiconductor substrate resin including silicon, or the like. The positive electrode 104 may be disposed on the substrate 102 and may be formed by using indium tin oxide (ITO), indium zinc oxide (IZO), or the like. The hole injection layer 106 may be disposed on the positive electrode 104 and may include 4,4′,4″-tris(N-1-naphtyl-N-phenylamino) triphenylamine (1-TNATA), 4,4-bis(N,N-di(3-tolyl)amino-3,3-dimethylbiphenyl (HMTPD), and the like. The hole transport layer 108 may be disposed on the hole injection layer 106 and may be formed by using the hole transport material for the organic EL device according to the inventive concept. The emission layer 110 may be disposed on the hole transport layer 108 and may be forming by doping tetra-t-butylperylene (TBP) into a host material including, e.g., 9,10-di(2-naphtyl)anthracene (ADN). The electron transport layer 112 may be disposed on the emission layer 110 and may be formed by using a material including, e.g., tris(8-hydroxyquinolinato)aluminum (Alq3). The electron injection layer 114 may be disposed on the electron transport layer 112 and may be formed by using a material including, e.g., lithium fluoride (LiF). The negative electrode 116 may be formed on the electron injection layer 114 and may be formed by using a metal such as Al or a transparent material such as ITO, IZO, or the like. The above-described thin films may be formed by selecting a suitable thin film forming method according to the materials, e.g., a vacuum deposition method, a sputtering method, various coating methods, and the like.

In the organic EL device 100 according to the embodiment, a hole transport layer having high efficiency and long life may be formed by using the arylamine compound according to an embodiment as a hole transport material for an organic EL device. The arylamine compound according to an embodiment may also be applied in an organic EL device of an active matrix using a thin film transistor (TFT).

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

### Synthetic Method

The above-described hole transport material for an organic EL device according to an embodiment was synthesized according to the following Reaction Scheme 1.

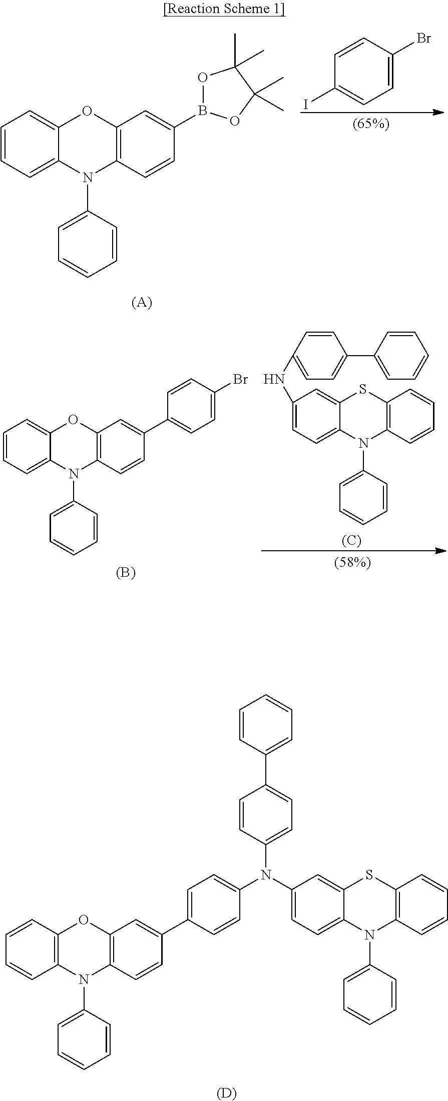

Synthesis of Bromophenyl Compound B

6.02 g (15.6 mmol) of boronic acid pinacolato (Compound A), and 4.87 g (17.2 mmol) of 4-bromo-1-iodo-benzene were added into a mixture solution of 200 ml of toluene, 200 ml of a 2M-aqueous sodium carbonate solution, and 100 ml of isopropanol. 903 mg (0.782 mmol) of tetrakis(triphenylphosphine)palladium (0) was added and stirred. Air was removed and replaced with argon. The reactant was stirred and refluxed for 5 hours, and then was cooled to room temperature. The reactant was extracted using toluene, washed using water and a saturated saline solution in order, and dried using anhydrous magnesium sulfate. The organic layer thus obtained was filtered and concentrated to obtain a residue. The residue was purified by a silica gel chromatography (cyclohexane/toluene=1/10→1/1) to obtain 4.21 g (10.2 mmol) of bromophenyl Compound B.

Synthesis of Arylamine Compound D

915 mg (2.21 mmol) of bromophenyl Compound B, 1.08 g (2.43 mmol) of arylamine Compound C, 69 mg (0.066 mmol) of tris(dibenzylideneacetone) dipalladium(0)•chloroform complex, and 637 mg (6.63 mmol) of sodium-t-butoxide were added into 100 ml of xylene and stirred. Air was removed while stirring and replaced with argon. Into the reactant, 0.088 ml (1.5M in toluene, 0.13 mmol) of tri-t-butylphosphine was added and the reactant was stirred and refluxed for 10 hours, and then cooled to room temperature. The reactant was extracted using toluene, washed using water and a saturated saline solution in order, and dried using anhydrous magnesium sulfate. The organic layer thus obtained was filtered and concentrated to obtain a residue. The residue was purified by a silica gel chromatography (cyclohexane/toluene=10/1→1/1) and recrystallized using toluene/ethanol to obtain 995 mg (1.28 mmol) of an arylamine Compound D.

The synthesized compounds were identified by measuring mass spectrum.

According to the above-described preparation methods, a compound of Example 1 was obtained. For example, the compound of Example 1 corresponds with Compound 7, above. For comparison, compounds of Comparative Example 1 and Comparative Example 2 were also prepared. The compounds of Example 1, Comparative Example 1, and Comparative Example 2 are illustrated below.

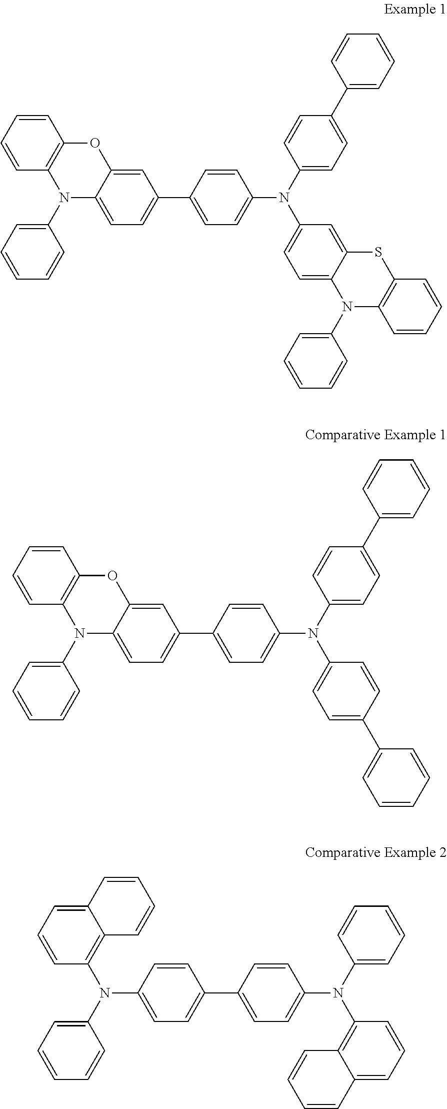 [SMILES: c1ccc(-c2ccc(N(c3ccc(-c4ccc5c(c4)Oc4ccccc4N5c4ccccc4)cc3)c3ccc4c(c3)Sc3ccccc3N4c3ccccc3)cc2)cc1 ; c1ccc(-c2ccc(N(c3ccc(-c4ccccc4)cc3)c3ccc(-c4ccc5c(c4)Oc4ccccc4N5c4ccccc4)cc3)cc2)cc1 ; c1ccc(N(c2ccc(-c3ccc(N(c4ccccc4)c4cccc5ccccc45)cc3)cc2)c2cccc3ccccc23)cc1]

By using the compounds of Example 1, Comparative Example 1, and Comparative Example 2 as hole transport materials, organic EL devices were manufactured. For example, the substrate 102 was formed by using a transparent glass substrate, the positive electrode 104 was formed by using ITO having a thickness of about 150 nm, the hole injection layer 106 was formed by using 1-TNATA having a thickness of about 60 nm, the hole transport layer 108 was formed (using the compounds described above, respectively) to a thickness of about 30 nm, the emission layer 110 was obtained by doping TBP by 3% into ADN was formed to a thickness of about 25 nm, the electron transport layer 112 was formed by using Alq3 to a thickness of about 25 nm, the electron injection layer 114 was formed by using LiF to a thickness of about 1 nm, and the negative electrode 116 was formed by using Al to a thickness of about 100 nm.

With respect to the manufactured organic EL devices, a driving voltage, current efficiency, and half-life were evaluated. The current efficiency was measured at about 10 mA/cm², and the half-life meant the half-life of luminance from an initial luminance of about 1,000 cd/m². The evaluation results are illustrated in the following Table 1.

| | Driving voltage | Current efficiency | Half-life |
|---|---|---|---|
| | (V) | (cd/A) | (hr) |
| Example 1 | 7.3 | 6.5 | 2,100 |
| Comparative | 7.8 | 6.5 | 1,500 |
| Example 1 | | | |
| Comparative | 8.1 | 6.3 | 1,200 |
| Example 2 | | | |

As may be seen in Table 1, the organic EL device including the compound of Example 1 was driven at a voltage lower than the organic EL device including the compound of Comparative Example 2. The current efficiency for the compound of Example 1 and the compounds of Comparative Examples 1 and 2 were about the same and within a practical range. Without being bound by theory, it would be suggested that the charge transport performance was improved by introducing a dibenzopiperidine derivative substituent, and the electron durability was improved by introducing a phenoxazinyl group or a phenothiazinyl group in the arylamine compound in the compound of Example 1. With respect to the half-life, the compound of Example 1 exhibited a very long life, when compared to the compounds of Comparative Examples 1 and 2. In the compound of Example 1, different substituents were disposed at three bonding sites of a tertiary amine, and an asymmetric structure is obtained overall. In addition, stacking effect between molecules may be lowered by introducing the dibenzopiperidine derivative substituent. Therefore, the stability of the organic EL device may be considered to be improved.

The stacking effect may be generated by overlapping adjacent molecules, and the lowering of the stacking effect may be explained by the dibenzopiperidine derivative having the piperidine derivative of a 6-member ring at a center thereof and tending to form a smoothly crooked structure. This structure may be a partial structure forming an organic EL material and may be compared to fluorene, carbazole, or dibenzofuran. The fluorene, the carbazole, and the dibenzofurane have a 5-member ring at a center thereof.

The stacking effect may be generated by the interaction between molecules, and may generate charge transport properties. Therefore, the restraining of the stacking effect while remaining certain interaction may be significant when designing a molecule. The restraining method of the stacking effect may be a significant factor in restraining the generation of minute crystals in a formed organic layer in the embodiments. Thus, the organic EL device may be stabilized by restraining abnormal charge distribution or abnormal charge transport during driving.

By way of summation and review, an organic EL device used for a display apparatus may have high efficiency and long life of the organic EL device. For realizing the high efficiency and long life, normalization, stabilization and durability of the hole transport layer may be considered.

The embodiments may provide an arylamine compound used as a hole transport material of an electroluminescence device having high efficiency and long life.

Improving durability with respect to electrons invading a hole transport layer may be important in obtaining an organic EL device having high efficiency and long life. In addition, the crystallization of a hole transport material while forming a hole transport layer may be restrained in order to obtain an organic EL device having long life.

The embodiments may provide an arylamine compound as a hole transport material of an organic EL device having high efficiency and long life.

The arylamine compound according to an embodiment may include different structures of one pair of a connecting part and a dibenzopiperidine derivative substituent, connected to the nitrogen of an arylamine. Thus, crystallization of the hole transport material while forming a hole transport layer may be restrained, and the life of the organic EL device may be increased.

In the arylamine compound according to an embodiment, charge transport performance may be improved, and durability with respect to electrons not used for light-emitting but invading into a hole transport layer may be improved. By using the arylamine compound according to the embodiment, the stability of the hole transport material may be improved, and an organic EL device having a low driving voltage and long life may be accomplished.

In the organic EL device according to an embodiment, a hole transport layer may be formed by using an arylamine compound including a pair of different structures containing a connecting part or linking group and a dibenzopiperidine derivative substituent, connected to the nitrogen of an arylamine. Thus, the crystallization of the hole transport layer may be restrained, and long life may be accomplished.

The organic EL device according to an embodiment may include an arylamine compound having a dibenzopiperidine derivative substituent of which X is a carbon atom, a nitrogen atom, an oxygen atom, or a sulfur atom, and a dibenzopiperidine derivative substituent of which Y is an oxygen atom or a sulfur atom. Thus, the charge transport performance of a hole transport layer may be improved, and the durability of electrons not used in light emitting but invading into the hole transport layer may be increased. Therefore, the stability of the hole transport material may be improved, and the organic EL device having a low driving voltage and long life may be accomplished.

According to an embodiment, an arylamine compound as a hole transport material of an organic EL device having high efficiency and long life, and an organic EL device using the same may be provided.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An arylamine compound represented by following Formula 1: 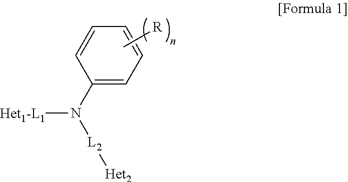
wherein:
a structure represented by Het₁-L₁ and a structure represented by Het₂-L₂ are different,
L₁ and L₂ are each independently a single bond or a bivalent group derived from an alkane, an arene, or a heteroarene having 1 to 20 carbon atoms,
Het₁ and Het₂ are each independently a dibenzopiperidine derivative substituent having less than or equal to 20 carbon atoms, and
R is a hydrogen atom, a deuterium atom, a fluorine atom, a chlorine atom, a cyano group, a trifluoromethyl group, a nitro group, a substitutable alkyl group having a straight or branched chain of 1 to 6 carbon atoms, a substitutable cycloalkyl group of 5 to 20 carbon atoms, a substitutable alkenyl group having a straight or branched chain of 2 to 6 carbon atoms, a substitutable alkyloxy group having a straight or branched chain of 1 to 6 carbon atoms, a substitutable cycloalkyloxy group, a substituted or unsubstituted aromatic hydrocarbon group, a substituted or unsubstituted aromatic heterocyclic group, a substituted or unsubstituted condensed polycyclic aromatic group, or a substituted or unsubstituted aryloxy group having 5 to 20 carbon atoms, in which monovalent, divalent, or adjacent two substituents may have a cyclic structure, and n is an integer of 0 to 7.

2. The arylamine compound as claimed in claim 1, wherein the arylamine compound is represented by following Formula 2: 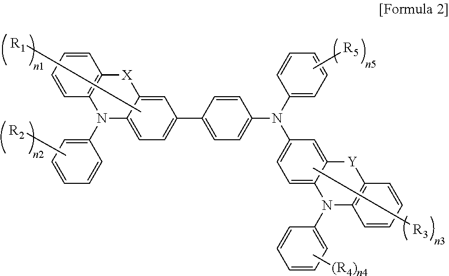
wherein:
X is a methylene group, a nitrogen atom, an oxygen atom, or a sulfur atom,
Y is a methylene group, an oxygen atom, or a sulfur atom, and
R₁ to R₅ are each independently a hydrogen atom, a deuterium atom, a fluorine atom, a chlorine atom, a cyano group, a trifluoromethyl group, a nitro group, a substitutable alkyl group having a straight or branched chain of 1 to 6 carbon atoms, a substitutable cycloalkyl group of 5 to 20 carbon atoms, a substitutable alkenyl group having a straight or branched chain of 2 to 6 carbon atoms, a substitutable alkyloxy group having a straight or branched chain of 1 to 6 carbon atoms, a substitutable cycloalkyloxy group, a substituted or unsubstituted aromatic hydrocarbon group, a substituted or unsubstituted aromatic heterocyclic group, a substituted or unsubstituted condensed polycyclic aromatic group, or a substituted or unsubstituted aryloxy group having 5 to 20 carbon atoms, in which monovalent, divalent or adjacent two substituents may have a cyclic structure, and n₁ to n₅ are each independently an integer of 0 to 7.

3. An organic electroluminescence device comprising a hole transport layer formed by using a compound represented by following Formula 1: 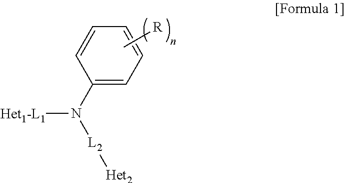
wherein:
a structure represented by Het₁-L₁ and a structure represented by Het₂-L₂ are different,
L₁ and L₂ are each independently a single bond or a bivalent group derived from an alkane, an arene, or a heteroarene having 1 to 20 carbon atoms,
Het₁ and Het₂ are each independently a dibenzopiperidine derivative substituent having less than or equal to 20 carbon atoms, and
R is a hydrogen atom, a deuterium atom, a fluorine atom, a chlorine atom, a cyano group, a trifluoromethyl group, a nitro group, a substitutable alkyl group having a straight or branched chain of 1 to 6 carbon atoms, a substitutable cycloalkyl group of 5 to 20 carbon atoms, a substitutable alkenyl group having a straight or branched chain of 2 to 6 carbon atoms, a substitutable alkyloxy group having a straight or branched chain of 1 to 6 carbon atoms, a substitutable cycloalkyloxy group, a substituted or unsubstituted aromatic hydrocarbon group, a substituted or unsubstituted aromatic heterocyclic group, a substituted or unsubstituted condensed polycyclic aromatic group, or a substituted or unsubstituted aryloxy group having 5 to 20 carbon atoms, in which monovalent, divalent, or adjacent two substituents may have a cyclic structure, and n is an integer of 0 to 7.

4. The organic electroluminescence device of claim 3, wherein the arylamine compound is represented by following Formula 2: 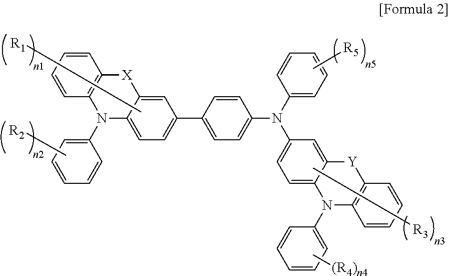
wherein:
X is a methylene group, a nitrogen atom, an oxygen atom, or a sulfur atom,
Y is a methylene group, an oxygen atom, or a sulfur atom, and
R₁ to R₅ are each independently a hydrogen atom, a deuterium atom, a fluorine atom, a chlorine atom, a cyano group, a trifluoromethyl group, a nitro group, a substitutable alkyl group having a straight or branched chain of 1 to 6 carbon atoms, a substitutable cycloalkyl group of 5 to 20 carbon atoms, a substitutable alkenyl group having a straight or branched chain of 2 to 6 carbon atoms, a substitutable alkyloxy group having a straight or branched chain of 1 to 6 carbon atoms, a substitutable cycloalkyloxy group, a substituted or unsubstituted aromatic hydrocarbon group, a substituted or unsubstituted aromatic heterocyclic group, a substituted or unsubstituted condensed polycyclic aromatic group, or a substituted or unsubstituted aryloxy group having 5 to 20 carbon atoms, in which monovalent, divalent or adjacent two substituents are separate or have a cyclic structure, and n₁ to n₅ are each independently an integer of 0 to 7.
